(19) United States
(12) Patent Application Publication
(10) Pub. No.: US 2017/0170013 A1
(43) Pub. Date: Jun. 15, 2017

(54) Display Panel and Method for Fabricating the Same

(71) Applicant: Shenzhen China Star Optoelectronics Technology Co., Ltd., Shenzhen, Guangdong (CN)

(72) Inventor: Xudong ZHANG, Shenzhen, Guangdong (CN)

(73) Assignee: Shenzhen China Star Optoelectronics Technology Co., Ltd., Shenzhen, Guangdong (CN)

(21) Appl. No.: 14/781,529

(22) PCT Filed: Jul. 17, 2015
(86) PCT No.: PCT/CN2015/084331

§ 371 Date: Sep. 30, 2015

(30) Foreign Application Priority Data
Jul. 13, 2015 (CN) 201510410386.8

(51) Int. Cl. H01L 21/02; H01L 29/04

(52) U.S. Cl. CPC H01L 21/02532; H01L 21/02488; H01L 21/02592; H01L 21/0262; H01L 21/02675; H01L 21/02502; H01L 29/04

(57) ABSTRACT

A display panel and a method for fabricating the display panel are proposed. The method includes steps of forming an amorphous silicon (a-Si) film on a substrate, the a-Si film comprising at least two a-Si layers, and densities of dice of the two adjacent a-Si layers being different; and transforming the a-Si film into a polycrystalline silicon film. The poly-silicon layer have less grain boundaries and larger dice, thereby increasing carrier mobility of the poly-silicon film and correspondingly improving the performance of the display panel.

### BACKGROUND OF THE INVENTION

1. Field of the Invention

The present invention relates to the field of display technology, and more particularly, to a display panel and a method for fabricating the same.

2. Description of the Prior Art

Nowadays, technology related to liquid crystal displays (LCDs) develops rapidly. The application of thin-film transistors (TFTs) improves the LCDs to become the mainstream products of flat displays, and the TFTs are used in personal computers (PCs), monitors, game consoles, and other products. Since amorphous silicon (a-Si) TFTs can be produced in low temperatures between 200° C. and 300° C., the a-Si TFTs are widely used. However, carrier mobility of a-Si is smaller, which cannot satisfy the demands of current high-speed units. That's why polycrystalline silicon (poly-silicon) TFTs are commonly used presently. Compared with a-Si TFTs, poly-silicon TFTs are more suitable for high-speed units owing to relatively larger carrier mobility and low-temperature sensitivity.

Traditionally, a-Si is transformed into poly-silicon by means of laser annealing to produce conventional poly-silicon. But, since the density of dice of poly-silicon and the density of dice of a-Si are different in the process of crystallization of a-Si, it is quite easy to generate many cavities and many grain boundaries between the dice after crystallization, resulting in smaller carrier mobility and poor performance of the corresponding display panel.

### SUMMARY OF THE INVENTION

An object of the present invention is to resolve the problem that the dice of a poly-silicon film used in the conventional display panel are lower and carrier mobility is smaller due to too many grain boundaries.

According to the present invention, a method for fabricating a display panel, comprises steps of: forming an amorphous silicon (a-Si) film on the substrate by means of chemical vapor deposition (CVD, the a-Si film comprising a first a-Si layer with a lower density of dice on the substrate and a second a-Si layer with a higher density of dice on the first a-Si layer; and transforming the a-Si film into a polycrystalline silicon (poly-silicon) film.

Furhtermore, a step of transforming the a-Si film into a poly-silicon film comprises: transforming the a-Si film into the poly-silicon film by means of laser annealing.

According to the present invention, a method for fabricating a display panel comprises steps of: forming an amorphous silicon (a-Si) film on a substrate, the a-Si film comprising at least two a-Si layers, and densities of dice of the two adjacent a-Si layers being different; transforming the a-Si film into a polycrystalline silicon (poly-silicon) film.

Furhtermore, a step of forming an a-Si film on the substrate comprises: forming a first a-Si layer with a lower density of dice on the substrate; and forming a second a-Si layer with a higher density of dice on the first a-Si layer.

Furhtermore, a step of forming an a-Si film on the substrate comprises: forming a first a-Si layer with a higher density of dice on the substrate; and forming a second a-Si layer with a lower density of dice on the first a-Si layer.

Furhtermore, a step of forming an a-Si film on the substrate comprises: forming the a-Si film on the substrate by means of chemical vapor deposition (CVD).

Furhtermore, a step of forming the a-Si film on the substrate by means of CVD comprises: forming a first a-Si layer on the substrate; and forming a second a-Si layer on the first a-Si layer by changing parameters so that the density of dice of the second a-Si layer is different from the density of dice of the first a-Si layer.

Furhtermore, the parameter comprises air pressure, voltage, and/or gas flow.

Furhtermore, a step of transforming the a-Si film into a poly-silicon film comprises: transforming the a-Si film into the poly-silicon film by means of laser annealing.

Furhtermore, steps before the step of forming the a-Si film on the substrate comprise: forming a buffer layer on the substrate. Tthe step of forming an a-Si film on the substrate comprises: forming an a-Si film on the buffer layer.

Furhtermore, a step of forming the buffer layer on the substrate comprises: forming a silicon nitride layer on the substrate; and forming a silicon dioxide layer on the silicon nitride layer.

According to the present invention, a display panel comprises a substrate and a poly-silicon film disposed on the substrate. The poly-silicon film comprises at least two a-Si layers transformed by an a-Si film. Densities of dice of the two adjacent a-Si layers are different.

Furhtermore, the a-Si film comprises a first a-Si layer with a lower density of dice formed on the substrate and a second a-Si layer with a higher density of dice formed on the first a-Si layer.

Furhtermore, the a-Si film comprises a first a-Si layer with a higher density of dice formed on the substrate and a second a-Si layer with a lower density of dice formed on the first a-Si layer.

Furhtermore, the a-Si film is formed on the substrate by means of chemical vapor deposition (CVD).

Furhtermore, the a-Si film comprises a first a-Si layer formed on the substrate by means of CVD and a second a-Si layer formed on the first a-Si layer by means of CVD after parameters of the CVD are adjusted, and the density of dice of the first a-Si layer is different from the density of dice of the second a-Si layer.

Furhtermore, the parameter comprises air pressure, voltage, and/or gas flow.

Furhtermore, the a-Si film transforms into the poly-silicon film by means of laser annealing.

Furhtermore, the display panel further comprises a buffer layer disposed between the substrate and the a-Si film.

Furhtermore, the buffer layer comprises a silicon nitride layer on the substrate and a silicon dioxide layer thereon.

In contrast to prior art, the feature of the present invention is as follows: At first, an a-Si film is formed on a substrate. The a-Si film comprises at least two a-Si layers. The densities of dice of the two adjacent a-Si layers are different. Afterwards, the a-Si film is transformed into a poly-silicon layer. When the two a-Si layers with different densities of dice are transformed into a poly-silicon layer, the a-Si layer with a higher density of dice will be downsized in the process of crystallization while the a-Si layer with a lower density of dice will be expanded. Such a combination can effectively reduces grain boundaries and produce larger dice, thereby increasing carrier mobility of the poly-silicon film and correspondingly improving the performance of the display panel.

### BRIEF DESCRIPTION OF THE DRAWINGS

FIG. 1 is a flow chart of a method for fabricating a display panel according to a first embodiment of the present invention.

FIG. 2 is a schematic diagram of the substrate and the first a-Si film used in the method as shown in FIG. 1 according to the first embodiment.

FIG. 3 is a schematic diagram of the substrate and the second a-Si film used in the method as shown in FIG. 1 according to the first embodiment.

FIG. 4 is a schematic diagram of transforming the first a-Si film into the poly-silicon film.

FIG. 5 is a flow chart of a method for fabricating a display panel according to a second embodiment of the present invention.

FIG. 6 is a schematic diagram of the structure of each film layer formed on a substrate used in the method as shown in FIG. 5 according to the second embodiment.

FIG. 7 is a schematic diagram of the structure of a display panel according to the first embodiment.

FIG. 8 is a schematic diagram of the structure of a display panel according to the second embodiment.

### DETAILED DESCRIPTION OF THE PREFERRED EMBODIMENTS

Please refer to FIG. 1. FIG. 1 is a flow chart of a method for fabricating a display panel according to a first embodiment of the present invention. The method comprises steps of:

Step S101: Forming an a-Si film on a substrate.

A substrate can be fabricated from either quartz or glass. A quartz substrate can endure a higher temperature compared with a glass substrate. Conventionally, it requires more than 600° C. to transform a-Si to poly-silicon. Because the glass substrate tends to be softened and distorted under 600° C., a quartz substrate is generally adopted. However, compared with a glass substrate, a quartz substrate is much expensive. The larger the size of a display panel is, the larger the size of a substrate is needed. Taking the price into consideration, manufacturers must choose and use glass substrates. At this time, glass substrates are conducted in a low-temperature state to transform a-Si to poly-silicon. Glass substrates are adopted in the present embodiment.

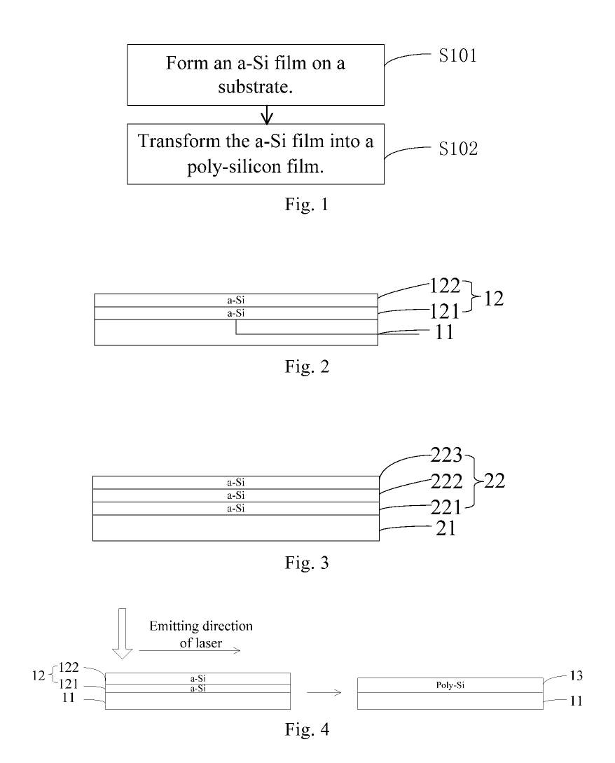

An a-Si film formed on a glass substrate comprises at least two a-Si layers. The densities of dice of the two adjacent a-Si layers are different. Please refer to FIG. 2 and FIG. 3. FIG. 2 is a schematic diagram of the substrate and the first a-Si film used in the method as shown in FIG. 1 according to the first embodiment. FIG. 3 is a schematic diagram of the substrate and the second a-Si film used in the method as shown in FIG. 1 according to the first embodiment.

In FIG. 2, an a-Si film 12 is formed on a glass substrate 11. The a-Si film 12 comprises a first a-Si layer 121 and a second a-Si layer 122. A-Si represents amorphous silicon in FIG. 2. In the other figures in this specification, a-Si represents amorphous silicon as well.

Specifically, the first a-Si layer 121 with a lower density of dice is formed on the substrate 11 by means of chemical vapor deposition (CVD). Then, parameters of CVD, such as air pressure, voltage, and/or gas flow, are changed. Then, the second a-Si layer 122 with a higher density of dice is formed on the first a-Si layer 121.

In the practical manufacturing process, a professional CVD device is used. There are two corresponding methods. The first method comprises: forming the a-Si film 12 all at once with the CVD device; specifically, putting the substrate 11 in the CVD device; depositing the first a-Si layer 121 on the surface of the substrate 11; regulating parameters of the CVD device after the first a-Si layer 121 is solidified in the vacuum cavity of the CVD device; subsequently, depositing the second a-Si layer 122 on the first a-Si layer 121. The second method comprises: putting the substrate 11 in the CVD device; depositing the first a-Si layer 121 on the surface of the substrate 11; retrieving the substrate 11 where the first a-Si layer 121 is deposited from the CVD device, and drying the first a-Si layer 121 in the atmospheric environment; then, regulating parameters of the CVD device; then, putting the substrate 11 in the CVD device, and depositing the second a-Si layer 122 on the first a-Si layer 121. Compared the first method with the second method, the first method takes more time while the a-Si layer is solidified in the vacuum cavity according to the first method, and the a-Si layer is dried in the atmospheric environment according to the second method. Compared with the first method, a problem that oxidation happens in the atmospheric environment easily occurs in the second method. Therefore, the first method is better than the second method when an a-Si film is transformed into a poly-silicon film. The performance of the poly-silicon film adopting the first method is better.

It is also allowable that the second a-Si layer 122 with the lower density of dice is formed on the first a-Si layer 121 after the first a-Si layer 121 with the higher density of dice is formed on the substrate 11.

Please refer to FIG. 3. An a-Si layer film 22 is formed on a glass substrate 21. The a-Si layer film 22 comprises a first a-Si layer 221, a second a-Si layer 222, and a third a-Si layer 223.

The method for forming the a-Si layer as shown in FIG. 3 is the same as that as shown in FIG. 2. But in FIG. 3, the density of dice of the first a-Si layer 221 is lower, the density of dice of the second a-Si layer 222 is higher, and the density of dice of the third a-Si layer 223 is lower. Likewise, the combination of the densities of the dice in the three a-Si layers may be higher, lower, and higher. There are many different combinations for the a-Si film comprising four, five or a plurality of a-Si layers such as higher, lower, higher, and lower. It should ensure that the densities of dice of two adjacent a-Si layers are different. The more the layers are, the better performance of a subsequently formed poly-silicon film is. However, the more layers are, the more time the corresponding CVD needs. Therefore, it is advisable to consider time cost and product quality comprehensively and then arrange proper numbers of a-Si layers.

Step S102: Transforming the a-Si film into a poly-silicon film.

After the a-Si film is formed on the glass substrate, the a-Si film is transformed into the poly-silicon film by means of laser annealing. The a-Si film can be transformed into the poly-silicon in a condition of about 400° C. through laser annealing. The glass substrate can bear 400° C. to the utmost. Other low-temperature techniques can be adopted in other embodiment where poly-silicon films are formed in lower temperatures.

Please refer to FIG. 4. FIG. 4 is a schematic diagram of transforming the first a-Si film into the poly-silicon film. Poly-Si shown in FIG. 4 represents polycrystalline silicon (poly-silicon). In the other figures in this specification, Poly-Si represents polycrystalline silicon (poly-silicon) as well. The a-Si film 12 is transformed into the poly-silicon film 13 by means of laser annealing in this embodiment.

The density of dice in the first a-Si layer 121 is lower so the structure of the first a-Si layer 121 is sparser. When the first a-Si layer 121 is transformed into the poly-silicon layer, the first a-Si layer 121 is downsized. The density of dice in the second a-Si layer 122 is higher so the structure of the second a-Si layer 122 is more compact. When the second a-Si layer 122 is transformed into the poly-silicon layer, the size of the second a-Si layer 122 is expanded. The combination of the first a-Si layer 121 and the first a-Si layer 121 helps reduction of formation of cavities, reduction of the number of grain boundaries, improvement of formation of larger dice, enhancement of corresponding carrier mobility, and improvement the performance of the display panel.

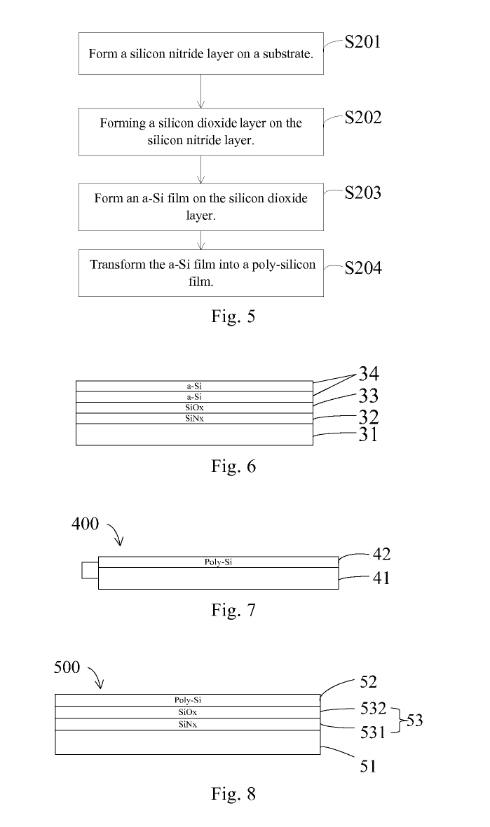

Please refer to FIG. 5 and FIG. 6. FIG. 5 is a flow chart of a method for fabricating a display panel according to a second embodiment of the present invention. FIG. 6 is a schematic diagram of the structure of each film layer formed on a substrate used in the method as shown in FIG. 5 according to the second embodiment. The method proposed by the second embodiment comprises following steps of:

Step S201: Forming a silicon nitride layer on a substrate.

Step S202: Forming a silicon dioxide (SiO₂) layer on the silicon nitride layer.

A silicon nitride layer 32 is formed on a substrate 31 in Step S201. A silicon dioxide layer 33 is formed on the silicon nitride layer 32 in Step S202. The silicon nitride layer 32 and the silicon dioxide layer 33 are used as a buffer layer between the substrate 31 and an a-Si film 34. That is, the silicon nitride layer 32 and the silicon dioxide layer 33 are formed by means of CVD and used for preventing impurities in the substrate 31 from entering the a-Si film 34. It is notified that SiOx represents silicon dioxide and SiNx represents silicon nitride in FIG. 6.

In other embodiments, it is allowable to use the silicon dioxide layer only while the silicon nitride layer contains a better shielding effect, actually. So the buffer layer in the present embodiment comprises the silicon nitride layer 32 and the silicon dioxide layer 33. Besides, the silicon dioxide layer 33 is formed on the silicon nitride layer 32 so that the a-Si film 34 can be formed on the silicon dioxide layer 33. The silicon dioxide layer 33 can be also used in a subsequent process—doping.

Step S203: Forming an a-Si film on the silicon dioxide layer.

Step S204: Transforming the a-Si film into a poly-silicon film.

What Step S203 and Step S204 introduce is similar to what Step S101 and Step S102 introduce. No further descriptions are provided in this specification.

Compared with the conventional technology, the a-Si film introduced in the present invention comprises at least two a-Si layers. The densities of dice of two adjacent a-Si layers are different. When the a-Si film is transformed into a poly-silicon film, the dice of the poly-silicon film are higher, and the grain boundaries of the poly-silicon film are smaller. Carrier mobility of the poly-silicon film is larger, and correspondingly the performance of the display panel is better.

Further, a display panel is proposed by the present invention. Please refer to FIG. 7. FIG. 7 is a schematic diagram of the structure of a display panel 400 according to the first embodiment. The display panel 400 comprises a substrate 41 and a poly-silicon film 42 formed on the substrate 41.

The poly-silicon film 42 is transformed by the a-Si film. The a-Si film comprises at least two a-Si layers. The densities of dice of two adjacent a-Si layers are different. The grain boundaries of the poly-silicon film 42 are less. The dice of the poly-silicon film 42 are higher. Carrier mobility is larger as well. Therefore, the performance of the corresponding display panel 400 is better.

The display panel 400 is fabricated based on the above-mentioned method proposed by the first embodiment.

FIG. 8 is a schematic diagram of the structure of a display panel 500 according to the second embodiment. The display panel 500 comprises a substrate 51, a poly-silicon film 52, and a buffer layer 53 arranged on an area between the substrate 51 and the poly-silicon film 52.

The poly-silicon film 52 is transformed by the a-Si film. The a-Si film comprises at least two a-Si layers. The densities of dice of two adjacent a-Si layers are different. The grain boundaries of the poly-silicon film 52 are less. The dice of the poly-silicon film 52 are higher. Carrier mobility is larger as well. Therefore, the performance of the corresponding display panel 500 is better. The buffer layer 53 in the present embodiment comprises a silicon nitride layer 531 and a silicon dioxide layer 532. The silicon nitride layer 531 is arranged on the substrate 51. The silicon dioxide layer 532 is arranged on the silicon nitride layer 531.

The display panel 500 is fabricated based on the above-mentioned method proposed by the second embodiment.

Compared with the conventional technology, carrier mobility of the poly-silicon film in the display panels provided by the present invention is larger. Also, the performance of the display panels provided by the present invention is better.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. A method for fabricating a display panel, comprising steps of:
forming an amorphous silicon (a-Si) film on the substrate by means of chemical vapor deposition (CVD, the a-Si film comprising a first a-Si layer with a lower density of dice on the substrate and a second a-Si layer with a higher density of dice on the first a-Si layer; and
transforming the a-Si film into a polycrystalline silicon (poly-silicon) film.

2. The method of claim 1, wherein a step of transforming the a-Si film into a poly-silicon film comprises:
transforming the a-Si film into the poly-silicon film by means of laser annealing.

3. A method for fabricating a display panel, comprising steps of:
forming an amorphous silicon (a-Si) film on a substrate, the a-Si film comprising at least two a-Si layers, and densities of dice of the two adjacent a-Si layers being different;
transforming the a-Si film into a polycrystalline silicon (poly-silicon) film.

4. The method of claim 3, wherein a step of forming an a-Si film on the substrate comprises:
forming a first a-Si layer with a lower density of dice on the substrate;
forming a second a-Si layer with a higher density of dice on the first a-Si layer.

5. The method of claim 3, wherein a step of forming an a-Si film on the substrate comprises:
forming a first a-Si layer with a higher density of dice on the substrate;
forming a second a-Si layer with a lower density of dice on the first a-Si layer.

6. The method of claim 3, wherein a step of forming an a-Si film on the substrate comprises:
forming the a-Si film on the substrate by means of chemical vapor deposition (CVD).

7. The method of claim 6, wherein a step of forming the a-Si film on the substrate by means of CVD comprises:
forming a first a-Si layer on the substrate;
forming a second a-Si layer on the first a-Si layer by changing parameters so that the density of dice of the second a-Si layer is different from the density of dice of the first a-Si layer.

8. The method of claim 7, wherein the parameter comprises air pressure, voltage, and/or gas flow.

9. The method of claim 3, wherein a step of transforming the a-Si film into a poly-silicon film comprises:
transforming the a-Si film into the poly-silicon film by means of laser annealing.

10. The method of claim 3, wherein steps before the step of forming the a-Si film on the substrate comprise:
forming a buffer layer on the substrate;
the step of forming an a-Si film on the substrate comprises:
forming an a-Si film on the buffer layer.

11. The method of claim 10, wherein a step of forming the buffer layer on the substrate comprises:
forming a silicon nitride layer on the substrate;
forming a silicon dioxide layer on the silicon nitride layer.

12. A display panel, comprising a substrate and a poly-silicon film disposed on the substrate, the poly-silicon film comprising at least two a-Si layers transformed by an a-Si film, and densities of dice of the two adjacent a-Si layers being different.

13. The display panel of claim 12, wherein the a-Si film comprises a first a-Si layer with a lower density of dice formed on the substrate and a second a-Si layer with a higher density of dice formed on the first a-Si layer.

14. The display panel of claim 12, wherein the a-Si film comprises a first a-Si layer with a higher density of dice formed on the substrate and a second a-Si layer with a lower density of dice formed on the first a-Si layer.

15. The display panel of claim 12, wherein the a-Si film is formed on the substrate by means of chemical vapor deposition (CVD).

16. The display panel of claim 15, wherein the a-Si film comprises a first a-Si layer formed on the substrate by means of CVD and a second a-Si layer formed on the first a-Si layer by means of CVD after parameters of the CVD are adjusted, and the density of dice of the first a-Si layer is different from the density of dice of the second a-Si layer.

17. The display panel of claim 16, wherein the parameter comprises air pressure, voltage, and/or gas flow.

18. The display panel of claim 12, wherein the a-Si film transforms into the poly-silicon film by means of laser annealing.

19. The display panel of claim 12, further comprising a buffer layer disposed between the substrate and the a-Si film.

20. The display panel of claim 19, wherein the buffer layer comprises a silicon nitride layer on the substrate and a silicon dioxide layer thereon.
